(19) United States
(12) Patent Application Publication
(10) Pub. No.: US 2026/0026097 A1
(43) Pub. Date: Jan. 22, 2026

(54) TRANSISTOR STRUCTURE AND MANUFACTURING METHOD THEREOF

(71) Applicant: United Microelectronics Corp., Hsinchu (TW)

(72) Inventor: Shin-Hung Li, Nantou County (TW)

(73) Assignee: United Microelectronics Corp., Hsinchu (TW)

(21) Appl. No.: 18/806,702

(22) Filed: Aug. 16, 2024

(30) Foreign Application Priority Data
Jul. 17, 2024 (CN) 202410958743.3

(51) Int. Cl. H01L 27/092; H01L 21/28; H01L 21/8238; H01L 29/08

(52) U.S. Cl. CPC H10D 84/856; H01L 21/28211; H10D 62/151; H10D 84/017; H10D 84/0188; H10D 84/0193; H10D 84/038; H10D 84/853

(57) ABSTRACT

A transistor structure including the following components. An isolation structure defines an active region in a substrate. The isolation structure has a first recess and a second recess located on two sides of the active region. The first recess and the second recess respectively expose a first sidewall and a second sidewall of the substrate in the active region. A first epitaxial layer and a second epitaxial layer are respectively located on the first sidewall and the second sidewall. The first epitaxial layer is located in the first recess and is located on the isolation structure. The second epitaxial layer is located in the second recess and is located on the isolation structure. A gate dielectric layer is located on the substrate, the first epitaxial layer, and the second epitaxial layer. A gate electrode is located on the gate dielectric layer.

### CROSS-REFERENCE TO RELATED APPLICATION

This application claims the priority benefit of China application serial no. 202410958743.3, filed on Jul. 17, 2024. The entirety of the above-mentioned patent application is hereby incorporated by reference herein and made a part of this specification.

### BACKGROUND

### Technical Field

The invention relates to a semiconductor structure and a manufacturing method thereof, and particularly relates to a transistor structure and a manufacturing method thereof.

### Description of Related Art

The transistor device is an important device in the integrated circuit. However, how to further reduce the leakage current of the transistor device is the goal of continuous efforts at present.

### SUMMARY

The invention provides a transistor structure and a manufacturing method thereof, which can effectively reduce the leakage current.

The invention provides a transistor structure, which includes a substrate, an isolation structure, a first epitaxial layer, a second epitaxial layer, a gate dielectric layer, and a gate electrode. The isolation structure is located in the substrate. The isolation structure defines an active region in the substrate. The isolation structure has a first recess and a second recess located on two sides of the active region. The first recess and the second recess respectively expose the first sidewall and the second sidewall of the substrate in the active region. The first epitaxial layer and the second epitaxial layer are respectively located on the first sidewall and the second sidewall. The first epitaxial layer is located in the first recess and is located on the isolation structure. The second epitaxial layer is located in the second recess and is located on the isolation structure. The gate dielectric layer is located on the substrate, the first epitaxial layer, and the second epitaxial layer. The gate electrode is located on the gate dielectric layer.

According to an embodiment of the invention, in the transistor structure, the material of the first epitaxial layer is, for example, silicon (Si), silicon germanium (SiGe), or silicon phosphide (SiP). The material of the second epitaxial layer is, for example, silicon, silicon germanium, or silicon phosphide.

According to an embodiment of the invention, in the transistor structure, the first epitaxial layer may be in direct contact with the first sidewall.

According to an embodiment of the invention, in the transistor structure, the second epitaxial layer may be in direct contact with the second sidewall.

According to an embodiment of the invention, in the transistor structure, the bottom surface of the first recess may be lower than the top surface of the isolation structure.

According to an embodiment of the invention, in the transistor structure, the bottom surface of the second recess may be lower than the top surface of the isolation structure.

According to an embodiment of the invention, the transistor structure may further include a first drift region and a second drift region. The first drift region and the second drift region are located in the substrate on two sides of the gate electrode. The first drift region may be connected to the first epitaxial layer. The second drift region may be connected to the second epitaxial layer.

According to an embodiment of the invention, in the transistor structure, the bottom surface of the first drift region may be higher than the bottom surface of the isolation structure. The bottom surface of the second drift region may be higher than the bottom surface of the isolation structure.

According to an embodiment of the invention, the transistor structure may further include a first spacer and a second spacer. The first spacer and second spacer are located on the gate dielectric layer on two sides of the gate electrode.

According to an embodiment of the invention, in the transistor structure, the first spacer may be located directly above the first epitaxial layer. The second spacer may be located directly above the second epitaxial layer.

The invention provides a manufacturing method of a transistor structure, which includes the following steps. A substrate is provided. An isolation structure is formed in substrate. The isolation structure defines an active region in the substrate. The isolation structure has a first recess and a second recess located on two sides of the active region. The first recess and the second recess respectively expose the first sidewall and the second sidewall of the substrate in the active region. A first epitaxial layer and a second epitaxial layer are respectively formed on the first sidewall and the second sidewall. The first epitaxial layer is located in the first recess and is located on the isolation structure. The second epitaxial layer is located in the second recess and is located on the isolation structure. A gate dielectric layer is formed on the substrate, the first epitaxial layer, and the second epitaxial layer. A gate electrode is formed on the gate dielectric layer.

According to an embodiment of the invention, the manufacturing method of the transistor structure may further include the following step. The third recess is formed in the substrate before forming the isolation structure.

According to an embodiment of the invention, in the manufacturing method of the transistor structure, the isolation structure may be formed in the substrate exposed by the third recess.

According to an embodiment of the invention, in the manufacturing method of the transistor structure, the method of forming the isolation structure, the first recess, and the second recess may include the following steps. An isolation structure material layer is formed in substrate. The isolation structure material layer is patterned to form the isolation structure, the first recess, and the second recess.

According to an embodiment of the invention, the manufacturing method of the transistor structure may further include the following step. An etch back process is performed on the isolation structure.

According to an embodiment of the invention, in the manufacturing method of the transistor structure, the method of forming the first epitaxial layer and the second epitaxial layer is, for example, an epitaxial growth method.

According to an embodiment of the invention, in the manufacturing method of the transistor structure, the method of forming the gate dielectric layer is, for example, a thermal oxidation method.

According to an embodiment of the invention, the manufacturing method of the transistor structure may further include the following step. A first drift region and a second drift region are formed in the substrate on two sides of the gate electrode. The first drift region may be connected to the first epitaxial layer. The second drift region may be connected to the second epitaxial layer.

According to an embodiment of the invention, in the manufacturing method of the transistor structure, the bottom surface of the first drift region may be higher than the bottom surface of the isolation structure. The bottom surface of the second drift region may be higher than the bottom surface of the isolation structure.

According to an embodiment of the invention, the manufacturing method of the transistor structure may further include the following step. A first spacer and a second spacer are formed on the gate dielectric layer on two sides of the gate electrode.

Based on the above description, in the transistor structure and the manufacturing method thereof according to the invention, the first epitaxial layer and the second epitaxial layer are respectively located on the first sidewall and the second sidewall, the first epitaxial layer is located in the first recess and is located on the isolation structure, and the second epitaxial layer is located in the second recess and is located on the isolation structure, thereby effectively reducing the leakage current.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1G are cross-sectional views of a manufacturing process of a transistor structure according to some embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. In fact, the dimensions of the various features may be arbitrarily increased or reduced for clarity of discussion.

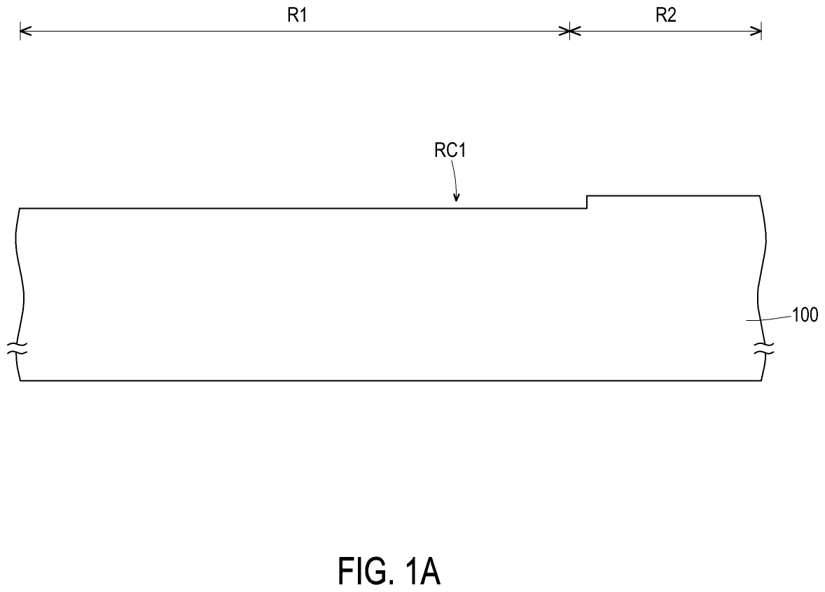

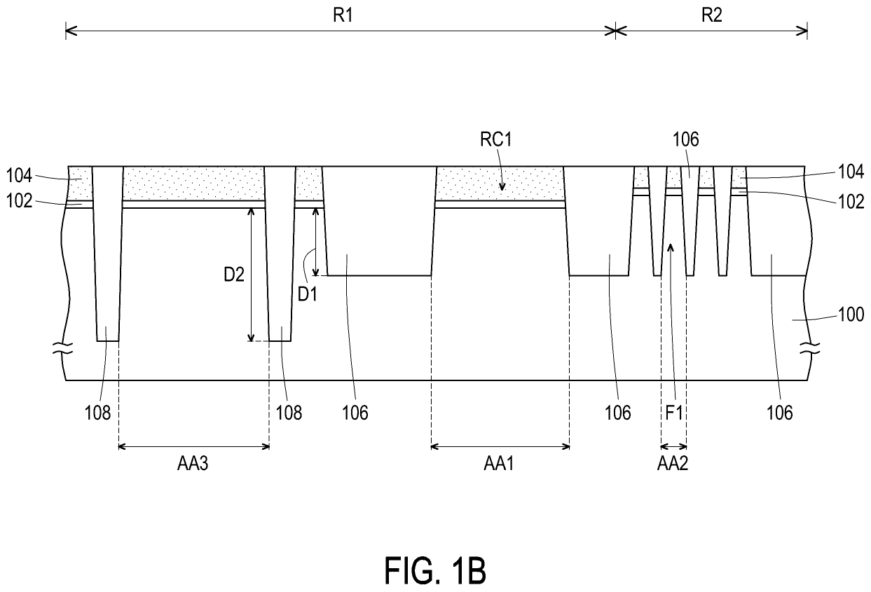

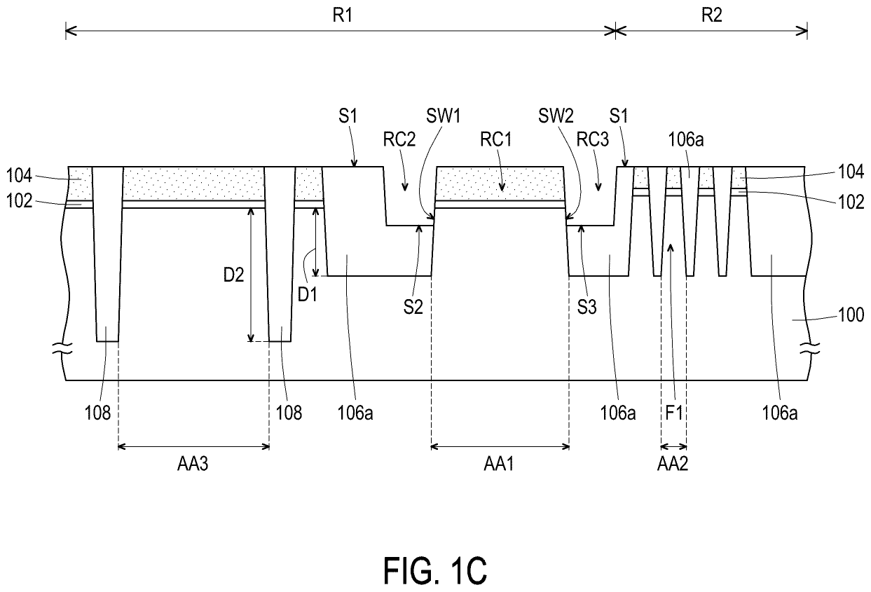

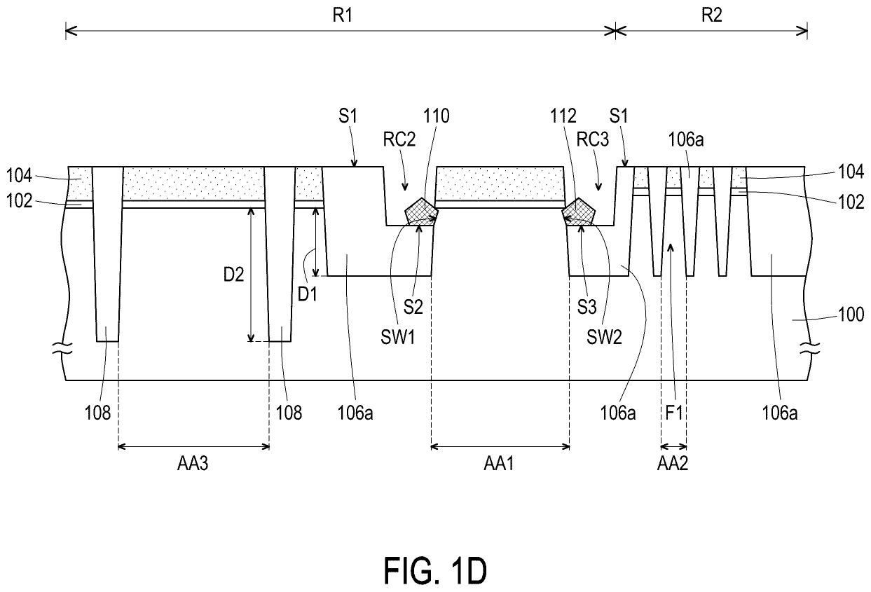

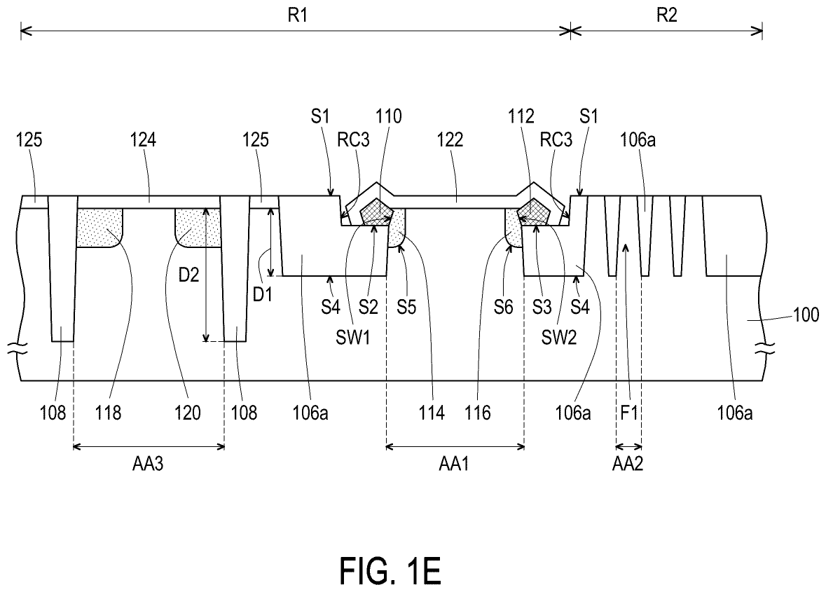

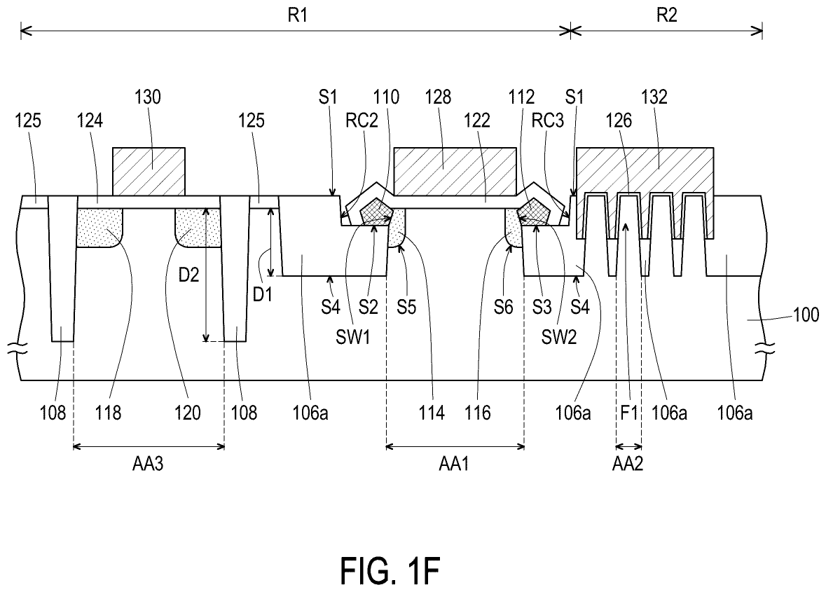

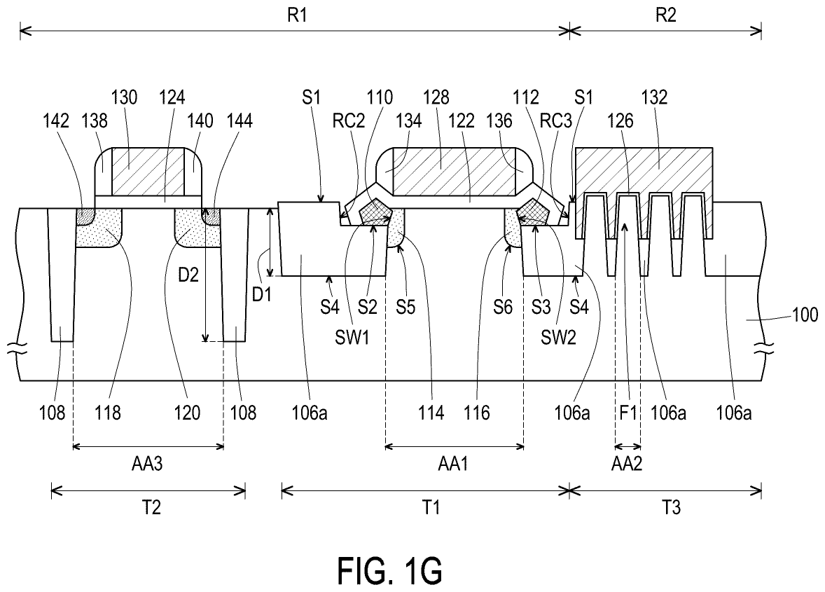

FIG. 1A to FIG. 1G are cross-sectional views of a manufacturing process of a transistor structure according to some embodiments of the invention.

Referring to FIG. 1A, a substrate 100 is provided. In some embodiments, the substrate 100 may include a first region R1 and a second region R2. In some embodiments, the first region R1 may be a medium voltage device region, and the second region R2 may be a low voltage device region. In some embodiments, the substrate 100 may be a semiconductor substrate such as silicon substrate.

A recess RC1 may be formed in the substrate 100. In some embodiments, the recess RC1 may be located in the first region R1. In some embodiments, the recess RC1 may be formed by patterning the substrate 100 by a lithography process and an etching process.

Referring to FIG. 1B, a pad layer 102 may be formed on the substrate 100. In some embodiments, the material of the pad layer 102 is, for example, silicon oxide. In some embodiments, the method of forming the pad layer 102 is, for example, a thermal oxidation method. A pad layer 104 may be formed on the pad layer 102. The material of the pad layer 104 is, for example, silicon nitride. In some embodiments, the method of forming the pad layer 104 is, for example, a chemical vapor deposition (CVD) method.

An isolation structure material layer 106 is formed in the substrate 100. In some embodiments, the isolation structure material layer 106 may be further formed in the pad layer 104 and the pad layer 102. The isolation structure material layer 106 defines an active region AA1 in the substrate 100. The active region AA1 may be located in the first region R1. In addition, the isolation structure material layer 106 may define an active region AA2 and a fin portion F1 in the second region R2. In some embodiments, the isolation structure material layer 106 may be a shallow trench isolation (STI) structure. In some embodiments, the material of the isolation structure material layer 106 is, for example, silicon oxide. In some embodiments, the isolation structure material layer 106 may be formed by a shallow trench isolation structure process.

In some embodiments, an isolation structure 108 may be formed in the substrate 100 in the first region R1. The isolation structure 108 may define an active region AA3 in the substrate 100 in the first region R1. The depth D2 of the isolation structure 108 in the substrate 100 may be greater than the depth D1 of the isolation structure material layer 106 in the substrate 100. In some embodiments, the isolation structure 108 may be a shallow trench isolation structure. In some embodiments, the material of the isolation structure 108 is, for example, silicon oxide. In some embodiments, the isolation structure 108 may be formed by a shallow trench isolation structure process.

Referring to FIG. 1C, the isolation structure material layer 106 is patterned to form an isolation structure 106a, a recess RC2, and a recess RC3. Therefore, the isolation structure 106a may be formed in the substrate 100. The isolation structure 106a may be formed in the substrate 100 exposed by the recess RC1. The isolation structure 106a defines the active region AA1 in the substrate 100. The active region AA1 may be located in the first region R1. In addition, the isolation structure 106a may define the active region AA2 and the fin portion F1 in the second region R2. The isolation structure 106a has the recess RC2 and the recess RC3 located on two sides of the active region AA1. The recess RC2 and the recess RC3 respectively expose the sidewall SW1 and the sidewall SW2 of the substrate 100 in the active region AA1. The bottom surface S2 of the recess RC2 may be lower than the top surface S1 of the isolation structure 106a. The bottom surface S3 of the recess RC3 may be lower than the top surface S1 of the isolation structure 106a.

Referring to FIG. 1D, an epitaxial layer 110 and an epitaxial layer 112 are respectively formed on the sidewall SW1 and the sidewall SW2. The epitaxial layer 110 is located in the recess RC2 and is located on the isolation structure 106a. The epitaxial layer 112 is located in the recess RC3 and is located on the isolation structure 106a. The epitaxial layer 110 may be in direct contact with the sidewall SW1. The epitaxial layer 112 may be in direct contact with the sidewall SW2. In some embodiments, the material of the epitaxial layer 110 is, for example, silicon, silicon germanium, or silicon phosphide. In some embodiments, the material of the epitaxial layer 112 is, for example, silicon, silicon germanium, or silicon phosphide. In some embodiments, the method of forming the epitaxial layer 110 and the epitaxial layer 112 is, for example, an epitaxial growth method.

Referring to FIG. 1E, the pad layer 104 may be removed. In some embodiments, the method of removing the pad layer 104 is, for example, a wet etching method. In some embodiments, the pad layer 102 may be removed. In some embodiments, the method of removing the pad layer 102 is, for example, a wet etching method.

In some embodiments, an etch back process may be performed on the isolation structure 106a and the isolation structure 108, thereby adjusting the height of the isolation structure 106a and the height of the isolation structure 108. In some embodiments, the etch back process is, for example, a dry etching method.

A drift region 114, a drift region 116, a drift region 118, and a drift region 120 may be formed in the substrate 100 in the first region R1. The drift region 114 and the drift region 116 may be located in the active region AA1. The drift region 118 and the drift region 120 may be located in the active region AA3. The drift region 114 may be connected to the epitaxial layer 110. The drift region 116 may be connected to the epitaxial layer 112. The bottom surface S5 of the drift region 114 may be higher than the bottom surface S4 of the isolation structure 106a. The bottom surface S6 of the drift region 116 may be higher than the bottom surface S4 of the isolation structure 106a.

A gate dielectric layer 122 is formed on the substrate 100, the epitaxial layer 110, and the epitaxial layer 112. In some embodiments, a gate dielectric layer 124 may be formed on the substrate 100 in the active region AA3. In some embodiments, a dielectric layer 125 may be formed on the substrate 100 aside the isolation structure 108. In some embodiments, the material of the gate dielectric layer 122, the material of the gate dielectric layer 124, and the material of the dielectric layer 125 are, for example, silicon oxide. In some embodiments, the method of forming the gate dielectric layer 122, the gate dielectric layer 124, and the dielectric layer 125 is, for example, a thermal oxidation method. In some embodiments, a patterned hard mask layer (not shown) covering the second region R2 may be formed before forming the gate dielectric layer 122, the gate dielectric layer 124, and the dielectric layer 125 by a thermal oxidation method. In addition, the patterned hard mask layer may be removed after forming the gate dielectric layer 122, the gate dielectric layer 124, and the dielectric layer 125.

Referring to FIG. 1F, a portion of the isolation structure 106a in the second region R2 may be removed to expose the sidewall of the fin portion F1. In some embodiments, the isolation structure 106a may be patterned by a lithography process and an etching process to remove a portion of the isolation structure 106a in the second region R2.

A gate dielectric layer 126 may be formed on the fin portion F1. In some embodiments, the material of the gate dielectric layer 126 is, for example, silicon oxide. In some embodiments, the method of forming the gate dielectric layer 126 is, for example, a thermal oxidation method.

A gate electrode 128 is formed on the gate dielectric layer 122. Furthermore, a gate electrode 130 may be formed on the gate dielectric layer 124, and a gate electrode 132 may be formed on the gate dielectric layer 126. In some embodiments, the material of the gate electrode 128, the material of the gate electrode 130, and the material of the gate electrode 132 are, for example, doped polysilicon. By the above method, the drift region 114 and the drift region 116 may be formed in the substrate 100 on two sides of the gate electrode 128, and the drift region 118 and the drift region 120 may be formed in the substrate 100 on two sides of the gate electrode 130.

Referring to FIG. 1G, a spacer 134 and a spacer 136 may be formed on the gate dielectric layer 122 on two sides of the gate electrode 128. In addition, a spacer 138 and a spacer 140 may be formed on the gate dielectric layer 124 on two sides of the gate electrode 130. In some embodiments, the spacer 134 may be located directly above the epitaxial layer 110. In some embodiments, the spacer 136 may be located directly above the epitaxial layer 112. The spacer 134, the spacer 136, the spacer 138, and the spacer 140 may be single-layer structures or multilayer structures. The material of the spacer 134, the material of the spacer 136, the material of the spacer 138, and the material of the spacer 140 are, for example, silicon oxide, silicon nitride, or a combination thereof.

A portion of the gate dielectric layer 124 and the dielectric layer 125 may be removed. In addition, a portion of the isolation structure 108 and a portion of the isolation structure 106a may be removed. A doped region 142 and a doped region 144 may be formed in the substrate 100 on two sides of the gate electrode 130. The doped region 142 and the doped region 144 may be respectively located in the drift region 118 and the drift region 120. In some embodiments, the doped region 142 and the doped region 144 may be used as source/drain regions.

By the above method, a transistor structure T1 and a transistor structure T2 may be formed in the first region R1, and a transistor structure T3 may be formed in the first region R2. The transistor structure T1 may include the substrate 100, the isolation structure 106a, the epitaxial layer 110, the epitaxial layer 112, the gate dielectric layer 122, the gate electrode 128, the drift region 114, the drift region 116, the spacer 134, and the spacer 136. The transistor structure T2 may include the substrate 100, the isolation structure 108, the gate dielectric layer 124, the gate electrode 130, the drift region 118, the drift region 120, the doped region 142, the doped region 144, the spacer 138, and the spacer 140. The transistor structure T3 may include the substrate 100, the isolation structure 106a, the gate dielectric layer 126, and the gate electrode 132.

Hereinafter, the transistor structure T1 of the present embodiment will be described with reference to FIG. 1G. In addition, although the method for forming the transistor structure T1 is described by taking the above method as an example, the invention is not limited thereto.

Referring to FIG. 1G, a transistor structure T1 includes a substrate 100, an isolation structure 106a, an epitaxial layer 110, an epitaxial layer 112, a gate dielectric layer 122, and a gate electrode 128. The isolation structure 106a is located in the substrate 100. The isolation structure 106a defines an active region AA1 in the substrate 100. The isolation structure 106a has a recess RC2 and a recess RC3 located on two sides of the active region AA1. The recess RC2 and the recess RC3 respectively expose the sidewall SW1 and the sidewall SW2 of the substrate 100 in the active region AA1. The epitaxial layer 110 and the epitaxial layer 112 are respectively located on the sidewall SW1 and the sidewall SW2. The epitaxial layer 110 is located in the recess RC2 and is located on the isolation structure 106a. The epitaxial layer 112 is located in the recess RC3 and is located on the isolation structure 106a. The gate dielectric layer 122 is located on the substrate 100, the epitaxial layer 110, and the epitaxial layer 112. The gate electrode 128 is located on the gate dielectric layer 122. The transistor structure T1 may further include a drift region 114 and a drift region 116. The drift region 114 and the drift region 116 are located in the substrate 100 on two sides of the gate electrode 128. The transistor structure T1 may further include a spacer 134 and a spacer 136. The spacer 134 and the spacer 136 are located on the gate dielectric layer 122 on two sides of gate electrode 128.

In addition, the details of each component in the transistor structure T1 (e.g., the material and the formation method) have been described in detail in the above embodiments, and the description thereof is not repeated here.

Based on the above embodiments, in the transistor structure T1 and the manufacturing method thereof, the epitaxial layer 110 and the epitaxial layer 112 are respectively located on the sidewall SW1 and the sidewall SW2, the epitaxial layer 110 is located in the recess RC2 and is located on the isolation structure 106a, and the epitaxial layer 112 is located in the recess RC3 and is located on the isolation structure 106a, thereby effectively reducing the leakage current.

In summary, in the transistor structure and the manufacturing method thereof in the aforementioned embodiments, the transistor structure includes a substrate, an isolation structure, a first epitaxial layer, a second epitaxial layer, a gate dielectric layer, and a gate electrode. The isolation structure is located in the substrate. The isolation structure defines an active region in the substrate. The isolation structure has a first recess and a second recess located on two sides of the active region. The first recess and the second recess respectively expose the first sidewall and the second sidewall of the substrate in the active region. The first epitaxial layer and the second epitaxial layer are respectively located on the first sidewall and the second sidewall, the first epitaxial layer is located in the first recess and is located on the isolation structure, and the second epitaxial layer is located in the second recess and is located on the isolation structure, thereby effectively reducing the leakage current.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A transistor structure, comprising:
a substrate;
an isolation structure located in the substrate and defining an active region in the substrate, wherein the isolation structure has a first recess and a second recess located on two sides of the active region, and the first recess and the second recess respectively expose a first sidewall and a second sidewall of the substrate in the active region;
a first epitaxial layer and a second epitaxial layer respectively located on the first sidewall and the second sidewall, wherein the first epitaxial layer is located in the first recess and is located on the isolation structure, and the second epitaxial layer is located in the second recess and is located on the isolation structure;
a gate dielectric layer located on the substrate, the first epitaxial layer, and the second epitaxial layer; and
a gate electrode located on the gate dielectric layer.

2. The transistor structure according to claim 1, wherein a material of the first epitaxial layer comprises silicon, silicon germanium, or silicon phosphide, and a material of the second epitaxial layer comprises silicon, silicon germanium, or silicon phosphide.

3. The transistor structure according to claim 1, wherein the first epitaxial layer is in direct contact with the first sidewall.

4. The transistor structure according to claim 1, wherein the second epitaxial layer is in direct contact with the second sidewall.

5. The transistor structure according to claim 1, wherein a bottom surface of the first recess is lower than a top surface of the isolation structure.

6. The transistor structure according to claim 1, wherein a bottom surface of the second recess is lower than a top surface of the isolation structure.

7. The transistor structure according to claim 1, further comprising:
a first drift region and a second drift region located in the substrate on two sides of the gate electrode, wherein
the first drift region is connected to the first epitaxial layer, and
the second drift region is connected to the second epitaxial layer.

8. The transistor structure according to claim 7, wherein
a bottom surface of the first drift region is higher than a bottom surface of the isolation structure, and
a bottom surface of the second drift region is higher than a bottom surface of the isolation structure.

9. The transistor structure according to claim 1, further comprising:
a first spacer and a second spacer located on the gate dielectric layer on two sides of the gate electrode.

10. The transistor structure according to claim 9, wherein
the first spacer is located directly above the first epitaxial layer, and
the second spacer is located directly above the second epitaxial layer.

11. A manufacturing method of a transistor structure, comprising:
providing a substrate;
forming an isolation structure in the substrate, wherein the isolation structure defines an active region in the substrate, the isolation structure has a first recess and a second recess located on two sides of the active region, and the first recess and the second recess respectively expose a first sidewall and a second sidewall of the substrate in the active region;
respectively forming a first epitaxial layer and a second epitaxial layer on the first sidewall and the second sidewall, wherein the first epitaxial layer is located in the first recess and is located on the isolation structure, and the second epitaxial layer is located in the second recess and is located on the isolation structure;
forming a gate dielectric layer on the substrate, the first epitaxial layer, and the second epitaxial layer; and
forming a gate electrode on the gate dielectric layer.

12. The manufacturing method of the transistor structure according to claim 11, further comprising:
forming a third recess in the substrate before forming the isolation structure.

13. The manufacturing method of the transistor structure according to claim 12, wherein the isolation structure is formed in the substrate exposed by the third recess.

14. The manufacturing method of the transistor structure according to claim 11, wherein a method of forming the isolation structure, the first recess, and the second recess comprises:
forming an isolation structure material layer in the substrate; and
patterning the isolation structure material layer to form the isolation structure, the first recess, and the second recess.

15. The manufacturing method of the transistor structure according to claim 11, further comprising:
performing an etch back process on the isolation structure.

16. The manufacturing method of the transistor structure according to claim 11, wherein a method of forming the first epitaxial layer and the second epitaxial layer comprises an epitaxial growth method.

17. The manufacturing method of the transistor structure according to claim 11, wherein a method of forming the gate dielectric layer comprises a thermal oxidation method.

18. The manufacturing method of the transistor structure according to claim 11, further comprising:
forming a first drift region and a second drift region in the substrate on two sides of the gate electrode, wherein
the first drift region is connected to the first epitaxial layer, and
the second drift region is connected to the second epitaxial layer.

19. The manufacturing method of the transistor structure according to claim 18, wherein
a bottom surface of the first drift region is higher than a bottom surface of the isolation structure, and
a bottom surface of the second drift region is higher than a bottom surface of the isolation structure.

20. The manufacturing method of the transistor structure according to claim 11, further comprising:
forming a first spacer and a second spacer on the gate dielectric layer on two sides of the gate electrode.
